(19) United States
(12) Patent Application Publication
(10) Pub. No.: US 2025/0125243 A1
(43) Pub. Date: Apr. 17, 2025

(54) CHIP CARRIER STRUCTURE

(71) Applicant: SILICONWARE PRECISION INDUSTRIES CO., LTD., Taichung City (TW)

(72) Inventors: Chung-Yen HUANG, Taichung City (TW); Yu-Tung YAO, Taichung City (TW); Jann-Tzung LIU, Taichung City (TW); Shu-Yu KO, Taichung City (TW); Hsiu-Fang CHIEN, Taichung City (TW)

(21) Appl. No.: 18/581,006

(22) Filed: Feb. 19, 2024

(30) Foreign Application Priority Data
Oct. 17, 2023 (TW) 112139631

(51) Int. Cl. H01L 23/498

(52) U.S. Cl. CPC H01L 23/49838; H01L 23/49866

(57) ABSTRACT

A chip carrier structure is provided and defined with a chip carrier region and a wire bonding region, and the chip carrier structure includes: an insulating layer; a circuit layer formed on the insulating layer; a solder mask layer formed on the insulating layer and the circuit layer and having a plurality of openings in the wire bonding region; and a protective layer formed on a portion of the circuit layer exposed from the solder mask layer, where an area of the protective layer in each of the openings is less than 70000 μm². By reducing the areas of the circuit layer exposed from the openings and the protective layer exposed from the openings, the problem of delamination caused by poor bonding force between the materials of the protective layer and the circuit layer is greatly reduced, thereby improving the reliability and lifespan of the chip carrier structure.

### BACKGROUND

### 1. Technical Field

The present disclosure relates to a chip carrier structure, and more particularly, to a chip carrier structure that reduces an area of a circuit layer exposed from a solder mask layer.

### 2. Description of Related Art

With the rapid and massive popularity of computer, communication and consumer electronics, various carrier substrates for mounting electronic elements and chips have also been developed and applied in large quantities. In current technology and applications, the circuit layer in the carrier substrate is primarily made of copper or copper alloy. This is because copper not only has good electrical conductivity, but also has many advantages such as easy availability, low cost, and easy processing. However, since the element of copper is also chemically active, it is easily oxidized when exposed to the atmospheric environment, forming copper oxide with extremely poor conductivity. Therefore, most of the exposed surfaces of copper circuits are covered with an anti-oxidation layer to isolate from the atmospheric environment. Gold plating on the surface of copper circuits has become a common process.

In addition, the carrier substrate usually has multiple circuit layers since today's electronic circuits are becoming more and more complex, so that different parts of the circuit are separately arranged in different circuit layers, and the sub-circuits that need to be connected are connected through conductive vias. For power supply or ground circuits that are used in almost every circuit layer, special layers are usually provided. In order to make the wiring of other complex circuit layers easier, continuous and large-area metal (copper) layers are often formed in the power supply and/or ground layers, especially in the ground layers. Moreover, the ground layer is often placed on the outermost layer of the carrier substrate.

FIG. 1 is a partially enlarged schematic view of a surface of a conventional wire bonding substrate. As shown in FIG. 1, a solder mask layer 11 is formed on the surface of the conventional wire bonding substrate. A wire bonding position is exposed in an opening 110 on the solder mask layer 11, and a lead 12 is soldered thereon. A continuously distributed metal ground plane 13 is also exposed around the wire bonding position. In order to prevent the copper in the exposed ground plane 13 from being oxidized, the surface of the exposed ground plane 13 is usually gold-plated. However, since gold has poor bonding force with almost all materials, and there are often various stresses at the interfaces of different materials, delamination often occurs between the plated gold layer and the underlying copper layer. As a result, the circuit of the entire carrier substrate cannot operate properly and fails, so that the reliability and lifespan of the electronic element containing the carrier substrate and even the product using the electronic element are reduced. Therefore, how to overcome the above-mentioned problems of the prior art has become an urgent issue in the industry.

### SUMMARY

In view of the various deficiencies of the prior art, the present disclosure provides a chip carrier structure being defined with a chip carrier region and a wire bonding region located around the chip carrier region, and the chip carrier structure comprises: an insulating layer; a circuit layer formed on the insulating layer; a solder mask layer formed on the insulating layer and the circuit layer, wherein a plurality of openings are formed in the wire bonding region and expose portions of the circuit layer and portions of the insulating layer; and a protective layer formed and stacked on the circuit layer exposed from the openings of the solder mask layer; wherein at least one spacer portion is formed at the circuit layer exposed from each of the openings and divides the circuit layer exposed in each of the openings into at least two blocks, such that an area of the circuit layer exposed from each of the openings and an area of the protective layer stacked on the circuit layer exposed from each of the openings are reduced.

In the aforementioned chip carrier structure, the protective layer is disposed with at least one soldering finger region thereabove.

In the aforementioned chip carrier structure, the protective layer is composed of gold.

In the aforementioned chip carrier structure, the circuit layer is composed of copper or copper-containing alloy.

In the aforementioned chip carrier structure, the area of the protective layer is less than or equal to the area of the circuit layer exposed from each of the openings.

In the aforementioned chip carrier structure, a thickness of the protective layer is less than a thickness of the circuit layer.

In the aforementioned chip carrier structure, the protective layer has a thickness between 0.3 μm and 1.2 μm.

In the aforementioned chip carrier structure, the area of the protective layer in each of the openings is less than 70000 μm².

In the aforementioned chip carrier structure, the spacer portion has a width greater than or equal to a minimum line spacing.

In the aforementioned chip carrier structure, the spacer portion has a width greater than or equal to 100 μm.

In the aforementioned chip carrier structure, a ratio of the area of the protective layer exposed from each of the openings to an area of the insulating layer exposed from each of the openings is less than or equal to 20%.

Via the implementation of the present disclosure, a spacer portion is added to the circuit layer in the opening of the solder mask layer in the wire bonding region to divide the circuit layer into at least two blocks, so as to reduce the areas of the circuit layer exposed in the opening and the protective layer stacked on the circuit layer, greatly reduce the delamination problem caused by poor bonding force between the materials of the protective layer and the circuit layer, and improve the reliability and lifespan of the chip carrier structure.

### BRIEF DESCRIPTION OF THE DRAWINGS

FIG. 1 is a partially enlarged schematic view of a surface of a conventional wire bonding substrate.

FIG. 2A is a schematic top view of a chip carrier structure according to the present disclosure.

FIG. 2B is a partially enlarged schematic view of FIG. 2A.

FIG. 2C is a partial cross-sectional schematic view of FIG. 2B.

FIG. 3 is a schematic view of a semiconductor package using the chip carrier structure according to the present disclosure.

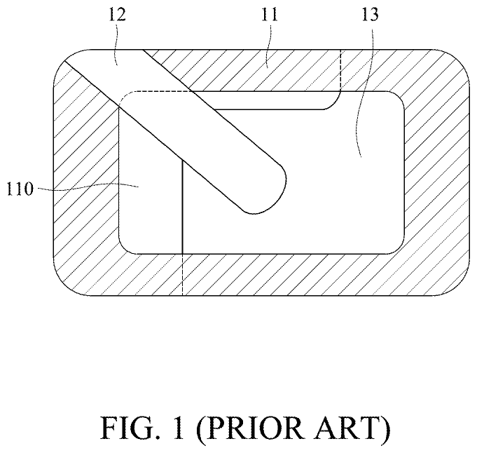

### DETAILED DESCRIPTION

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “above,” “on,” “upper,” “first,” “second,” “a,” “one” and the like are merely for clear explanation rather than limiting the practicable scope of the present disclosure, and thus, alterations or adjustments of the relative relationships thereof without essentially altering the technical contents should still be considered in the practicable scope of the present disclosure.

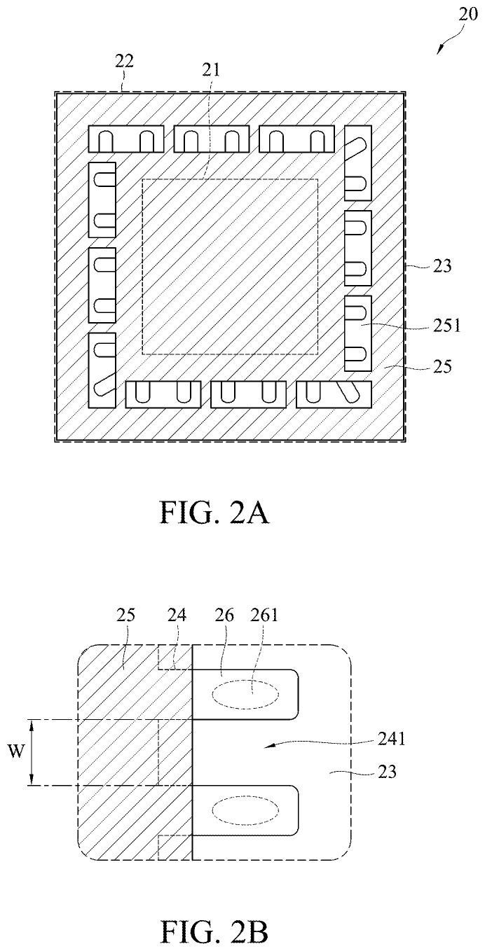

FIG. 2A is a schematic top view of a chip carrier structure according to the present disclosure; FIG. 2B is a partially enlarged schematic view of FIG. 2A; and FIG. 2C is a partial cross-sectional schematic view of a region shown in FIG. 2B. In an embodiment, as shown in FIG. 2A to FIG. 2C, a chip carrier structure 20 is provided, and a chip carrier region 21 and a wire bonding region 22 are defined on a surface of the chip carrier structure 20. The chip carrier structure 20 comprises: an insulating layer 23; a circuit layer 24 formed on the insulating layer 23; a solder mask layer 25 formed on the insulating layer 23 and the circuit layer 24, and having a plurality of openings 251 formed in the wire bonding region 22; and a protective layer 26 stacked on the circuit layer 24 exposed from the solder mask layer 25.

The insulating layer 23 may be a dielectric layer composed of dielectric materials such as polybenzoxazole (PBO), polyimide (PI), prepreg (PP) and the like.

The circuit layer 24 is formed on the insulating layer 23. The circuit layer 24 can be a power circuit, a ground circuit, or other circuits with various functions, or it can be any combination of the above circuits, and the present disclosure is not limited to as such. In an embodiment, in order to balance conductivity and cost, the circuit layer 24 is made of copper or a copper-containing alloy. In other embodiments, the circuit layer 24 can also be made of other different conductive materials, and is not limited to what is shown in the embodiment.

In addition, in most applications today, the chip carrier structure 20 is often a multi-layer structure. Therefore, in an embodiment, depending on the requirements, one or more circuit layers (not shown) can also be formed in the insulating layer 23 in addition to the circuit layer 24 formed on the surface of the insulating layer 23, and the present disclosure is not limited to as such.

The solder mask layer 25 is formed on the insulating layer 23 and the circuit layer 24, and the plurality of openings 251 are formed in the wire bonding region 22 at positions that need to be soldered later to expose the circuit layer 24 and part of the insulating layer 23 at these positions.

The circuit layer 24 in one embodiment is made of copper. In addition to copper, other copper-containing alloys may also be used, depending on the requirements for electrical and mechanical properties, and the present disclosure is not limited to as such. In an embodiment, in order to avoid that the circuit layer 24 exposed in each opening 251 will be oxidized after being in contact with the atmosphere so as to deteriorate the conductivity of the circuit layer 24 at these positions, the protective layer 26 is formed on the exposed portion of the circuit layer 24 in the opening 251 of the solder mask layer 25. In an embodiment, the protective layer 26 is formed by gold plating on the circuit layer 24. In other words, the protective layer 26 is made of gold to prevent the portion of the circuit layer 24 exposed in the opening 251 from oxidizing due to the stability of gold. Since gold is also a conductive metal material, the protective layer 26 made of gold can have an anti-oxidation effect while still maintaining the required conductivity.

At least one soldering finger region 261 is disposed above the protective layer 26 in each opening 251. Each soldering finger region 261 is a location intended to be soldered or wire bonded in subsequent applications. Since it is difficult to accurately control the shape and size of the soldering point regardless of soldering or wire bonding, at each soldering or wire bonding position, whether it is the circuit layer 24 or the protective layer 26, the area of the circuit layer 24 or the protective layer 26 exposed in the opening 251 will be set to be slightly larger than the soldering finger region 261. In an embodiment, since the protective layer 26 is formed by gold plating, that is, gold must be plated on the circuit layer 24 and attached to the circuit layer 24, the area of the protective layer 26 exposed in the opening 251 is larger than the area of the soldering finger region 261 and at the same time smaller than or equal to the area of the circuit layer 24 exposed in the opening 251. Preferably, the area of the protective layer 26 is equal to the area of the circuit layer 24 exposed in the opening 251.

In addition, since gold has poor bonding force with almost all materials, there is a risk that the protective layer 26 formed by gold plating will delaminate from the circuit layer 24. For this reason, the area of the protective layer 26 in the embodiment is limited as much as possible. For example, the ratio of the area of the protective layer 26 exposed from the opening 251 to the area of the insulating layer 23 exposed from the opening 251 is less than or equal to 20%. Preferably, in an embodiment, the area of the protective layer 26 corresponding to each soldering finger region 261 in each opening 251 is less than 70000 μm².

Similarly, considering that the protective layer 26 formed by gold plating has the risk of delamination, the thickness of the protective layer 26 is limited in an embodiment. As shown in FIG. 2C, the thickness of the protective layer 26 in an embodiment is limited to be smaller than the thickness of the circuit layer 24. This ensures that the body of matter of the protective layer 26 attached to the circuit layer 24 per unit area is not too high, thereby preventing the circuit layer 24 per unit area from being pulled by excessive protective layer 26 above and causing delamination. Preferably, in an embodiment, the thickness of the protective layer 26 is between 0.3 μm and 1.2 μm.

In addition, please refer to FIG. 2B again. In an embodiment, in order to avoid the problem of delamination of the protective layer 26 formed of gold plating, at least one spacer portion 241 can be formed at the circuit layer 24 exposed from the opening 251, so as to divide the circuit layer 24 exposed in the opening 251 into at least two blocks. The function of the spacer portion 241 is to limit the areas of the circuit layer 24 in the opening 251 and the protective layer 26 attached on the circuit layer 24 in the opening 251, so as to prevent continuous and large areas of the circuit layer 24 and the protective layer 26 on the circuit layer 24 from existing in the opening 251. When the areas of the circuit layer 24 and the protective layer 26 stacked and attached on the circuit layer 24 are reduced, the probability of occurrence of delamination problems will naturally decrease. This further improves the reliability and lifespan of the chip carrier structure 20 of the embodiment.

In practice, the circuit layer 24 on each chip carrier structure has a minimum line distance limit when wiring, so as to avoid the wirings of the circuits being too close to each other, and prevent signal distortion or transmission interference caused by the potential difference, induced electric field, induced magnetic field and/or capacitance between adjacent wirings. Therefore, the embodiment must also comply with these restrictions of electrical characteristics when reducing the scaling of the circuit layer 24 and the protective layer 26. At the same time, if the areas of the circuit layer 24 and the protective layer 26 are reduced too little, the effect of preventing delamination of the protective layer 26 will be limited. Therefore, in an embodiment, a width w of the spacer portion 241 is preferably greater than, or at least must be equal to, a minimum line spacing. Specifically, in an embodiment, the width w of the spacer portion 241 preferably must be greater than or equal to 100 μm.

To sum up, in the chip carrier structure 20 of the embodiment, the circuit layer 24 is divided into at least two blocks by, for example, adding the spacer portion 241 to the circuit layer 24 in the opening 251 of the solder mask layer 25 in the wire bonding region 22, so as to reduce the area of the circuit layer 24 exposed in the opening 251, greatly reduce the delamination problem caused by poor bonding force between the materials of the protective layer 26 and the circuit layer 24, and improve the reliability and lifespan of the chip carrier structure 20.

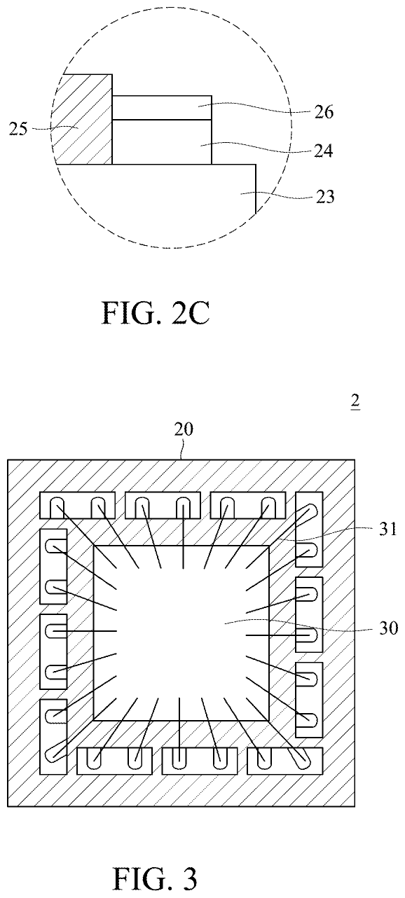

The chip carrier structure 20 obtained in the embodiment can be used, for example, in a semiconductor package 2 as shown in FIG. 3. In the semiconductor package 2, for example, a chip 30 is fixedly disposed in the chip carrier region 21 on the surface of the chip carrier structure 20, and then a plurality of bonding wires 31 are connected to the soldering finger regions 261 exposed in the openings 251 of each solder mask region in the wire bonding region 22 (see FIG. 2B) via the wire bonding technology, so as to achieve electrical connection with the circuit layer 24 of the chip carrier structure 20 demonstrated in the embodiment of the present disclosure. This improves the reliability and lifespan of the semiconductor package 2 using the chip carrier structure 20 of the present disclosure.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. A chip carrier structure being defined with a chip carrier region and a wire bonding region located around the chip carrier region, the chip carrier structure comprising:
an insulating layer;
a circuit layer formed on the insulating layer;
a solder mask layer formed on the insulating layer and the circuit layer, wherein a plurality of openings are formed in the wire bonding region and expose portions of the circuit layer and portions of the insulating layer; and
a protective layer formed and stacked on the portions of the circuit layer exposed from the openings of the solder mask layer;
wherein at least one spacer portion is formed on the portions of the circuit layer exposed from each of the openings and divides the portions of the circuit layer exposed from the openings of the solder mask into at least two blocks, such that an area of the circuit layer exposed from each of the openings and an area of the protective layer stacked on the circuit layer exposed from each of the openings are reduced.

2. The chip carrier structure of claim 1, wherein the protective layer is disposed with at least one soldering finger region thereabove.

3. The chip carrier structure of claim 1, wherein the protective layer is composed of gold.

4. The chip carrier structure of claim 1, wherein the circuit layer is composed of copper or copper-containing alloy.

5. The chip carrier structure of claim 1, wherein the area of the protective layer is less than or equal to the area of the circuit layer exposed from each of the openings.

6. The chip carrier structure of claim 1, wherein a thickness of the protective layer is less than a thickness of the circuit layer.

7. The chip carrier structure of claim 1, wherein the protective layer has a thickness between 0.3 μm and 1.2 μm.

8. The chip carrier structure of claim 1, wherein the area of the protective layer exposed from each of the openings is less than 70000 μm².

9. The chip carrier structure of claim 1, wherein the spacer portion has a width greater than or equal to a minimum line spacing.

10. The chip carrier structure of claim 1, wherein the spacer portion has a width greater than or equal to 100 μm.

11. The chip carrier structure of claim 1, wherein a ratio of the area of the protective layer exposed from each of the openings to an area of the insulating layer exposed from each of the openings is less than or equal to 20%.
